(19) United States
(12) Patent Application Publication
(10) Pub. No.: US 2024/0420745 A1
(43) Pub. Date: Dec. 19, 2024

(54) SENSE AMPLIFIER APPLIED TO NON-VOLATILE MEMORY

(71) Applicant: eMemory Technology Inc., Hsin-Chu (TW)

(72) Inventor: Wei-Ming KU, Hsinchu County (TW)

(21) Appl. No.: 18/629,972

(22) Filed: Apr. 9, 2024

Related U.S. Application Data
(60) Provisional application No. 63/472,616, filed on Jun. 13, 2023.

(51) Int. Cl. G11C 7/10; G11C 7/08; G11C 7/20

(52) U.S. Cl. CPC G11C 7/1069; G11C 7/08; G11C 7/20

(57) ABSTRACT

A sense amplifier for a non-volatile memory is provided. A first memory cell of the non-volatile memory is coupled to a data line. The sense amplifier includes a first switching device, a first voltage boosting circuit and a comparator. A first terminal of the first switching device is connected with the data line. A second terminal of the first switching device is connected with a ground terminal. A control terminal of the first switching device receives a reset signal. An input terminal of the first voltage boosting circuit is connected with the data line. An output terminal of the first voltage boosting circuit is connected with a sensing node. A first input terminal of the comparator receives a comparison voltage. A second input terminal of the comparator is connected with the sensing node. An output terminal of the comparator generates an output data.

This application claims the benefit of U.S. provisional application Ser. No. 63/472,616, filed Jun. 13, 2023, the subject matters of which are incorporated herein by references.

### FIELD OF THE INVENTION

The present invention relates to a sense amplifier, and more particularly to a sense amplifier for a non-volatile memory.

### BACKGROUND OF THE INVENTION

Generally, a memory cell array of a non-volatile memory comprises plural memory cells. Each memory cell at least comprises a selecting device and a storage device. For example, the storage device is a floating gate transistor, an antifuse type transistor or a resistive element. The operation of the storage device will be described as follows.

The floating gate of the floating gate transistor stores hot carriers (i.e., electrons). According to the number of the stored hot carriers, the storage state of the memory cell is determined. For example, during the program cycle of the non-volatile memory, the number of the hot carriers injected into the floating gate is controlled. Consequently, the threshold voltage of the floating gate transistor is adjusted. Consequently, the storage state of the memory cell is changed. During the read action, a read voltage is provided to the floating gate transistor. Consequently, a cell current (also referred as a read current) is generated. According to the magnitude of the cell current, the storage state of the memory cell is determined as a first storage state or a second storage state. For example, the floating gate transistor is a p-type floating gate transistor. If no hot carriers are stored in the floating gate during the read action, the cell current generated by the memory cell is very low (e.g., nearly zero). Under this circumstance, the storage state of the memory cell is determined as the first storage state. Whereas, if hot carriers are stored in the floating gate, the current cell generated by the memory cell is larger. Under this circumstance, the storage state of the memory cell is determined as the second storage state.

The antifuse type transistor comprises a gate dielectric layer. According to the result of judging whether the gate dielectric layer is ruptured, the storage state of the memory cell can be determined. When a program action of the non-volatile memory is performed, a program voltage is provided to the antifuse type transistor. Consequently, the gate dielectric layer of the antifuse type transistor is ruptured. Under this circumstance, the storage state of the memory cell is changed. When the read action is performed, a read voltage is provided to the antifuse type transistor. Consequently, a cell current (also referred as the read current) is generated. According to the magnitude of the cell current, the storage state of the memory cell is determined as a first storage state or a second storage state. For example, if the gate dielectric layer of the antifuse type transistor is not ruptured during the read action, the cell current generated by the memory cell is very low (e.g., nearly zero). Under this circumstance, the storage state of the memory cell is determined as the first storage state. Whereas, if the gate dielectric layer of the antifuse type transistor is ruptured during the read action, the cell current generated by the memory cell is larger. Under this circumstance, the storage state of the memory cell is determined as the second storage state.

Moreover, by providing various bias voltages to the resistive element, the resistance value of the resistive element is switched between a high resistance value and a low resistance value. According to the magnitude of the resistance value, the storage state of the memory cell is determined. For example, during the program cycle of the non-volatile memory, various bias voltages are provided to control the magnitude of the resistance value of the resistive element. During the read action, a read voltage is provided to the resistive element. Consequently, a cell current (also referred as a read current) is generated. According to the magnitude of the cell current, the storage state of the memory cell is determined as a first storage state or a second storage state.

As mentioned above, it is necessary to additionally provide a sense amplifier in the non-volatile memory. The sense amplifier is used to receive the cell current from the memory cell and judge the storage state of the memory cell.

### SUMMARY OF THE INVENTION

An embodiment of the present invention provides a sense amplifier for a non-volatile memory. A first memory cell of the non-volatile memory is coupled to a data line. The sense amplifier includes a first switching device, a first voltage boosting circuit and a comparator. A first terminal of the first switching device is connected with the data line. A second terminal of the first switching device is connected with a ground terminal. A control terminal of the first switching device receives a first control signal. The first control signal is a reset signal. An input terminal of the first voltage boosting circuit is connected with the data line. An output terminal of the first voltage boosting circuit is connected with a sensing node. A first input terminal of the comparator receives a comparison voltage. A second input terminal of the comparator is connected with the sensing node. An output terminal of the comparator generates an output data. In a reset phase of a read action, a data line voltage on the data line is reset to a ground voltage, and a sensing voltage at the sensing node is reset to the ground voltage. In a charge phase of the read action after the reset phase, the first memory cell generates a first cell current to charge the data line, and the sensing voltage is adjusted to the data line voltage under control of the first voltage boosting circuit. In a boost phase of the read action after the charge phase, the sensing voltage is adjusted to the data line voltage plus a first voltage increment under control of the first voltage boosting circuit. According to the comparison voltage and the sensing voltage, the comparator generates the output data to determine a storage state of the first memory cell.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic circuit diagram illustrating a memory cell of a non-volatile memory according to an embodiment of the present invention;

FIGS. 1B, 1C and 1D schematically illustrate the bias voltages provided to the memory cell of FIG. 1A when a program action is performed;

FIGS. 1E and 1F schematically illustrate the bias voltages provided to the memory cell of FIG. 1A when a read action is performed;

FIG. 2 is a schematic diagram illustrating the architecture of the non-volatile memory;

FIG. 3A is a schematic circuit diagram of a sense amplifier according to a first embodiment of the present invention;

FIGS. 3B and 3D are schematic circuit diagrams illustrating the operations of the sense amplifier when the read action is performed;

FIGS. 3C and 3E are schematic timing waveform diagrams illustrating associated signals of the sense amplifier when the read action is performed;

FIG. 3F is a plot illustrating the relationship between the drain-source voltage of the selecting transistor in the memory cell and the cell current;

FIG. 4 is a schematic circuit diagram of a sense amplifier according to a second embodiment of the present invention;

FIG. 5A is a schematic diagram illustrating the detailed circuitry structure of the sense amplifier according to the second embodiment;

FIGS. 5B, 5C and 5D schematically illustrate the operations of the sense amplifier according to the second embodiment of the present invention;

FIG. 5E is a schematic timing waveform diagram illustrating associated signals of the sense amplifier when the selected memory cell in the low-resistance state is sensed;

FIG. 5F is a schematic timing waveform diagram illustrating associated signals of the sense amplifier when the selected memory cell in the high-resistance state is sensed;

FIG. 6 is a schematic circuit diagram illustrating an example of the sense amplifier according to the second embodiment of the present invention, in which the voltage boosting circuit comprises plural boosting devices;

FIGS. 7A, 7B, 7C and 7D schematically illustrate the operations of the sense amplifier according to the second embodiment of the present invention, in which the voltage boosting circuit comprises two boosting devices;

FIG. 8 is a schematic circuit diagram of a sense amplifier according to a third embodiment of the present invention;

FIG. 9 is a schematic circuit diagram of a sense amplifier according to a fourth embodiment of the present invention; and

FIG. 10 is a schematic detail circuit diagram illustrating an exemplary boosting device in the sense amplifier of the present invention.

### DETAILED DESCRIPTION OF PREFERRED EMBODIMENTS

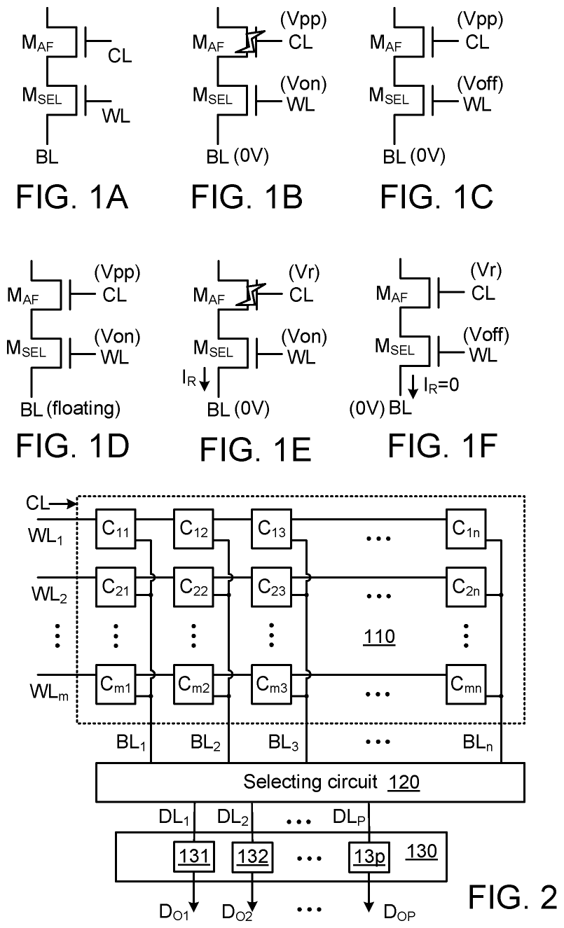

FIG. 1A is a schematic circuit diagram illustrating a memory cell of a non-volatile memory according to an embodiment of the present invention. FIGS. 1B, 1C and 1D schematically illustrate the bias voltages provided to the memory cell of FIG. 1A when a program action is performed. FIGS. 1E and 1F schematically illustrate the bias voltages provided to the memory cell of FIG. 1A when a read action is performed.

The non-volatile memory comprises a selecting device and a storage device. For example, the storage device is an antifuse type transistor M_{AF}, and the selecting device is a selecting transistor M_{SEL}. The first drain/source terminal of the selecting transistor M_{SEL} is connected with a bit line BL. The gate terminal of the selecting transistor M_{SEL} is connected with a word line WL. The first drain/source terminal of the antifuse type transistor M_{AF} is connected with the second drain/source of the selecting transistor M_{SEL}. The gate terminal of the antifuse type transistor M_{AF} is connected with a control line CL. The second drain/source terminal of the antifuse type transistor M_{AF} is in a floating state.

Generally, when the program action is performed, the memory cell is controlled to be in one of two different storage states. Please refer to FIG. 1B. When the program action is performed, the control line CL receives a program voltage Vpp, the bit line BL receives a ground voltage (0V), and the word line WL receives an on voltage Von. Meanwhile, the selecting transistor M_{SEL} is turned on, and the voltage stress withstood by the gate dielectric layer of the antifuse type transistor M_{AF} is equal to the program voltage Vpp. Consequently, the gate dielectric layer of the antifuse type transistor M_{AF} is ruptured. Under this circumstance, the memory cell is in the low-resistance storage state. For example, the program voltage Vpp is 5V, and the on voltage Von is 1.2V.

Please refer to FIG. 1C. When the program action is performed, the control line CL receives the program voltage Vpp, the bit line BL receives the ground voltage (0V), and the word line WL receives an off voltage Voff. Meanwhile, the selecting transistor M_{SEL} is turned off, and the voltage stress withstood by the gate dielectric layer of the antifuse type transistor M_{AF} is zero. Consequently, the gate dielectric layer of the antifuse type transistor M_{AF} is not ruptured. Under this circumstance, the memory cell is in the high-resistance storage state. The example of programming the memory cell to the high-resistance storage state is not restricted. Please refer to FIG. 1D. When the program action is performed, the bit line BL is in the floating state, and the word line WL receives the on voltage Von. Consequently, the memory cell is in the high-resistance storage state. For example, the off voltage Voff is 0V.

When the read action is performed, the storage state of the memory cell can be judged. Please refer to FIGS. 1E and 1F. When the read action is performed, the control line CL receives a read voltage Vr, the bit line BL receives the ground voltage (0V), and the word line WL receives the on voltage Von. As shown in FIG. 1E, the selecting transistor M_{SEL} is turned on. Since the gate dielectric layer of the antifuse type transistor M_{AF} is ruptured, the higher cell current I_{R} is generated on the bit line BL. As shown in FIG. 1F, the selecting transistor M_{SEL} is turned on. Since the gate dielectric layer of the antifuse type transistor M_{AF} is not ruptured, a very low cell current (e.g., I_{R}=0) is generated on the bit line BL. Consequently, when the read action is performed, one of the two storage states of the memory can be determined according to the magnitude of the cell current on the bit line BL. For example, the read voltage Vr is 2.5V.

It is noted that the storage device is not restricted to the antifuse type transistor. For example, in some other embodiments, the storage device in the memory cell of the non-volatile memory is a floating gate transistor or a resistive element. When the read action is performed, the storage state of the memory cell is determined according to the magnitude of the generated cell current.

FIG. 2 is a schematic diagram illustrating the architecture of the non-volatile memory. As shown in FIG. 2, the non-voltage memory comprises a memory cell array 110, a selecting circuit 120 and a sensing circuit 130. The memory cell array 110 comprises m×n memory cells C₁₁˜Cₘₙ, wherein m and n are positive integers. The storage devices of the memory cells C₁₁˜Cₘₙ are antifuse type transistors, floating gate transistors or resistive elements.

As shown in FIG. 2, all memory cells C₁₁˜Cₘₙ of the memory cell array 110 are connected with a control line CL. In the memory cell array 110, the n memory cells C₁₁˜C₁ₙ in the first row are connected with a word line WL₁. The n memory cells C₁₁˜C₁ₙ in the first row are respectively connected with the n bit lines BL₁˜BLₙ. The n memory cells C₂₁˜C₂ₙ in the second row are connected with a word line WL₂. The n memory cells C₂₁˜C₂ₙ in the second row are respectively connected with the n bit lines BL₁˜BLₙ. The rest may be deduced by analogy. The n memory cells Cm₁˜Cₘₙ in the m-th row are connected with a word line WLₘ. The n memory cells Cm₁˜Cₘₙ in the m-th row are respectively connected with the n bit lines BL₁˜BLₙ.

The selecting circuit 120 is connected with the n bit lines BL₁˜BLₙand p data lines DL₁˜DLₚ, wherein p is a positive integer, and p is smaller than or equal to n. When the read action is performed on the non-volatile memory, the selecting circuit 120 determines p bit lines from the n bit lines BL₁˜BLₙ, and the p bit lines are correspondingly respectively connected with the p data lines DL₁˜DLₚ.

The sensing circuit 130 comprises p sense amplifiers 131˜13p. The p sense amplifiers 131˜13p are respectively connected with the corresponding p data lines DL₁˜DLₚ. The circuitry structures of the p sense amplifiers 131˜13p are identical. When the read action is performed, the p sense amplifiers 131˜13p of the sensing circuit 130 receive cell currents from the corresponding data lines DL₁˜DLₚ, and a p-bit output data D_{O1}˜D_{OP} is generated to indicate the storage states of p selected memory cells. In other words, the sensing circuit 130 can judge the storage states of the p memory cells in the selected row once.

For example, n is 32, and p is 8. When the read action is performed and the word line WL₁ is activated, the first row is the selected row. Moreover, during a first sensing cycle, the bit lines BL₁˜BL₈ are respectively connected with the data lines DL₁˜DL₈ by the selecting circuit 120. Consequently, the eight memory cells C₁₁˜C₁₈ of the selected row are the selected memory cell. Under this circumstance, the cell currents generated by the selected memory cells C₁₁˜C₁₈ flow to the sensing circuit 130. According to the magnitudes of the cell currents on the data lines DL₁˜DL₈, the sensing circuit 130 generates a one-byte output data D_{O1}˜D_{O8} to indicate the storage states of the selected memory cell C₁₁˜C₁₈.

Similarly, during a second sensing cycle of the read action, the bit lines BL₉˜BL₁₆ are sequentially connected with the data lines DL₁˜DL₈ by the selecting circuit 120, and the sensing circuit 130 sequentially generates the corresponding output data D_{O1}˜D_{O8}. Similarly, during third sensing cycle of the read action, the bit lines BL₁₇˜BL₂₄ are sequentially connected with the data lines DL₁˜DL₈ by the selecting circuit 120, and the sensing circuit 130 sequentially generates the corresponding output data D_{O1}˜D_{O8}. Similarly, during a fourth sensing cycle of the read action, the bit lines BL₂₅˜BL₃₂ are sequentially connected with the data lines DL₁˜DL₈ by the selecting circuit 120, and the sensing circuit 130 sequentially generates the corresponding output data D_{O1}˜D_{O8}. Consequently, according to the four output data D_{O1}˜D_{O8} generated in the four sensing cycles, the sensing circuit 130 acquires the storage states of the 32 memory cells C₁₁˜C₁ₙ (i.e., n=32) in the first row (i.e., the selected row). Since the circuitry structures of the p sense amplifiers 131˜13p are identical, only the sense amplifier 131 and its operation principle will be described as follows.

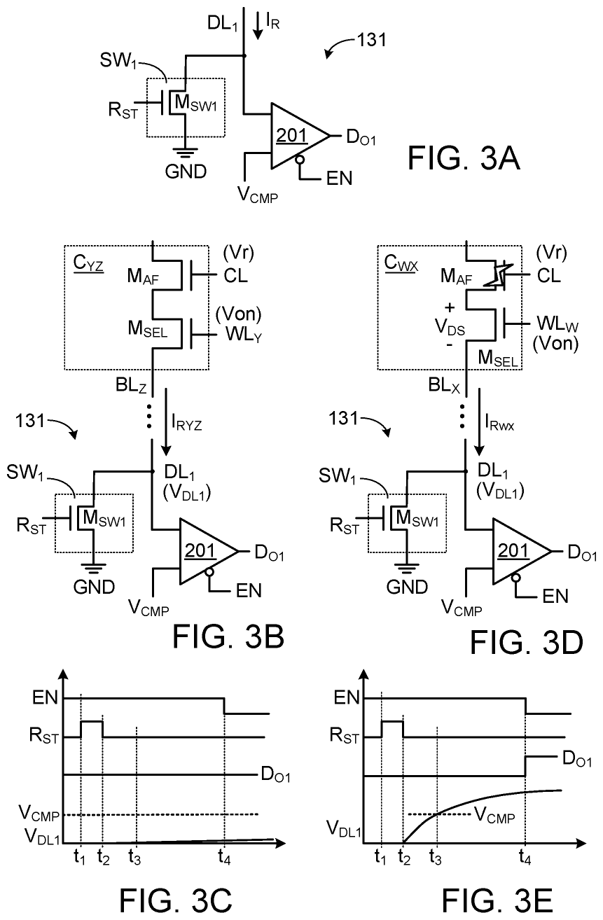

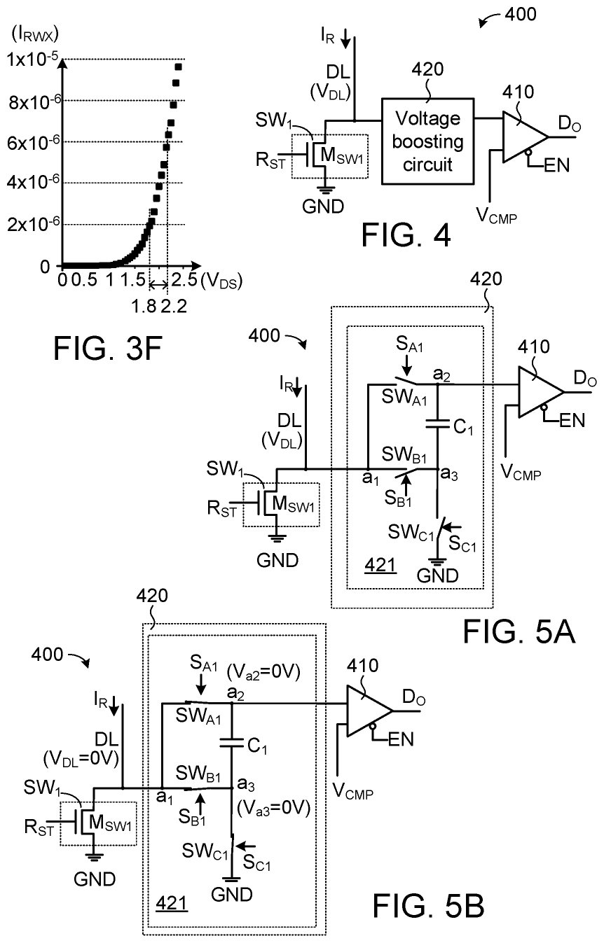

FIG. 3A is a schematic circuit diagram of a sense amplifier according to a first embodiment of the present invention.

The sense amplifier 131 comprises a switching device SW₁ and a comparator 201. The first terminal of the switching device SW₁ is connected with the data line DL₁. The second terminal of the switching device SW₁ is connected with a ground terminal GND. The control terminal of the switching device SW₁ receives a reset signal R_{ST}. The first input terminal of the comparator 201 receives a comparison voltage V_{CMP}. The second input terminal of the comparator 201 is connected with the data line DL₁. The output terminal of the comparator 201 generates the output data D_{O1}. In addition, the enable terminal of the comparator 201 receives an enable signal EN.

For example, the switching device is a switching transistor M_{SW1}. The first drain/source terminal of the switching transistor M_{SW1} is connected with the data line DL₁. The second drain/source terminal of the switching transistor M_{SW1} is connected with the ground terminal GND. The gate terminal of the switching transistor M_{SW1} receives the reset signal R_{ST}. Moreover, the comparator 201 is implemented with an operation amplifier.

When the read action is performed, a selected memory cell in the memory cell array 110 is coupled to the sense amplifier 131 through the selecting circuit 120. According to the cell current I_{R}, the storage state of the selected memory cell is determined by the sense amplifier 131. When the read action is performed, the operations of the sense amplifier will be understood by referring to FIGS. 3B to 3E.

FIGS. 3B and 3D are schematic circuit diagrams illustrating the operations of the sense amplifier when the read action is performed. FIGS. 3C and 3E are schematic timing waveform diagrams illustrating associated signals of the sense amplifier when the read action is performed.

Please refer to FIGS. 3B and 3C. When the read action is performed, the word lien WL_{Y} and the bit line BL_{Z} in the memory cell array are activated. The selected memory cell C_{YZ} is coupled to the data line DL₁ through the bit line BL_{Z}. In the time interval between the time point t₁ and the time point t₂, the reset signal R_{ST} is in a high-level state, and the switching transistor M_{SW1} is turned on. Meanwhile, the switching device SW₁ is in a close state, and the data line DL₁ is pulled down to the ground voltage. That is, the data line voltage V_{DL1} is 0V.

In the time interval between the time point t₂ and the time point t₄, the reset signal R_{ST} is in the low-level state, and the switching transistor M_{SW1} is turned off. Meanwhile, the switching device SW₁ is in an open state. The cell current I_{RYZ} charges the data line DL₁. Consequently, the data line voltage V_{DL1} starts to rise from 0V. Since the gate dielectric layer of the antifuse type transistor M_{AF} is not ruptured, the selected memory cell C_{YZ} generates a smaller cell current I_{RYZ} (e.g., nearly zero) to charge the data line DL₁. Consequently, the data line voltage V_{DL1} is very low and nearly unchanged. At the time point t₄, the enable signal EN is activated, and the comparator 210 is enabled. Since the data line voltage V_{DL1} is lower than the comparison voltage V_{CMP}, the comparator 210 generates a low-level output data D_{O1}. The low-level output data D_{O1} from the sense amplifier 131 indicates that the selected memory cell C_{YZ} is in a high-resistance storage state (e.g., a first storage state).

Please refer to FIGS. 3D and 3E. When the read action is performed, the word lien WL_{W} and the bit line BL_{X} in the memory cell array are activated. The selected memory cell C_{WX} is coupled to the data line DL₁ through the bit line BL_{X}. In the time interval between the time point t₁ and the time point t₂, the reset signal R_{ST} is in a high-level state, and the switching transistor M_{SW1} is turned on. Meanwhile, the switching device SW₁ is in a close state, and the data line DL₁ is pulled down to the ground voltage. That is, the data line voltage V_{DL1} is 0V.

In the time interval between the time point t₂ and the time point t₄, the reset signal R_{ST} is in the low-level state, and the switching transistor M_{SW1} is turned off. Meanwhile, the switching device SW₁ is in the open state. The cell current I_{RWX} charges the data line DL₁. Consequently, the data line voltage V_{DL1} starts to rise from 0V. Since the gate dielectric layer of the antifuse type transistor M_{AF} is ruptured, the selected memory cell C_{WX} generates a larger cell current I_{RWX} to charge the data line DL₁. After the time point t₃, the data line voltage V_{DL1} exceeds the comparison voltage V_{CMP}. At the time point t₄, the enable signal EN is activated, and the comparator 210 is enabled. Since the data line voltage V_{DL1} exceeds the comparison voltage V_{CMP}, the comparator 210 generates a high-level output data D_{O1}. The high-level output data D_{O1} from the sense amplifier 131 indicates that the selected memory cell C_{WX} is in a low-resistance storage state (e.g., a second storage state).

In FIGS. 3B to 3E, the low-level output data D_{O1} from the sense amplifier 131 indicates that the selected memory cell is in the first storage state, and the high-level output data D_{O1} from the sense amplifier 131 indicates that the selected memory cell is in the second storage state. In some other embodiments, the connection relationship between the comparator 201 and associated components is varied. Consequently, the high-level output data D_{O1} from the sense amplifier 131 indicates that the selected memory cell is in the first storage state, and the low-level output data D_{O1} from the sense amplifier 131 indicates that the selected memory cell is in the second storage state.

FIG. 3F is a plot illustrating the relationship between the drain-source voltage of the selecting transistor in the memory cell and the cell current.

Take the selected memory cell C_{WX} as shown in FIG. 3D for example. When the read action is performed, the word line WL_{W} receives an on voltage Von (e.g., 1.2V). In addition, the read voltage Vr is 2.5V. The cell current I_{RWX} charges the data line DL₁. Consequently, the data line voltage V_{DL1} starts to rise from 0V. Since the data line voltage V_{DL1} rises, the drain-source voltage V_{DS} of the selecting transistor M_{SEL} drops. Consequently, the magnitude of the cell current I_{RWX} decreases.

Please refer to FIG. 3F. In case that the drain-source voltage V_{DS} of the selecting transistor M_{SEL} is 2.2V, the cell current I_{RWX} is about 6 μA. In case that the drain-source voltage V_{DS} of the selecting transistor M_{SEL} is 1.8V, the cell current I_{RWX} is about 2 μA. In other words, as the drain-source voltage V_{DS} of the selecting transistor M_{SEL} changes from 2.2V to 1.8V, the magnitude of the cell current I_{RWX} decays by about three times.

When the read action is performed, the cell current I_{RWX} charges the data line DL₁. Consequently, the data line voltage V_{DL1} starts to rise. Since the data line voltage V_{DL1} rises, the drain-source voltage V_{DS} of the selecting transistor M_{SEL} drops. Consequently, the magnitude of the cell current I_{RWX} decays quickly, and the sensing time is too long. Alternatively, since the magnitude of the cell current I_{RWX} decays too quickly, the data line voltage V_{DL1} cannot exceed the comparison voltage V_{CMP}. Under this circumstance, the sense amplifier 131 is possibly suffered from misjudgment.

FIG. 4 is a schematic circuit diagram of a sense amplifier according to a second embodiment of the present invention. The sense amplifier 400 of the second embodiment is additionally equipped with a voltage boosting circuit 420. The voltage boosting circuit 420 is connected between the data line DL and the comparator 410. When the read action is performed, compared with the read action in the FIG. 3D, the drain-source voltage V_{DS} of the selecting transistor M_{SEL} in the embodiments of the present invention has a larger value, the selected memory cell can generate a larger cell current I_{R}, and the voltage boosting circuit 420 is able to boost the data line voltage V_{DL} quickly according to the larger cell current I_{R}. Consequently, the sense amplifier 400 can correctly judge the storage state of the selected memory cell.

The sense amplifier 400 comprises a switching device SW₁, a voltage boosting circuit 420 and a comparator 410. The first terminal of the switching device SW₁ is connected with the data line DL. The second terminal of the switching device SW₁ is connected with the ground terminal GND. The control terminal of the switching device SW₁ receives a reset signal R_{ST}.

The input terminal of the voltage boosting circuit 420 is connected with the data line DL. The first input terminal of the comparator 410 receives a comparison voltage V_{CMP}. The second input terminal of the comparator 410 is connected with the output terminal of the voltage boosting circuit 420. The enable terminal of the comparator 410 receives an enable signal EN. The output terminal of the comparator 410 generates an output data D_{O}.

The voltage boosting circuit 420 comprises at least one boosting device. The circuitry structure of the boosting device and the operating principles of the sense amplifier 400 will be described as follows.

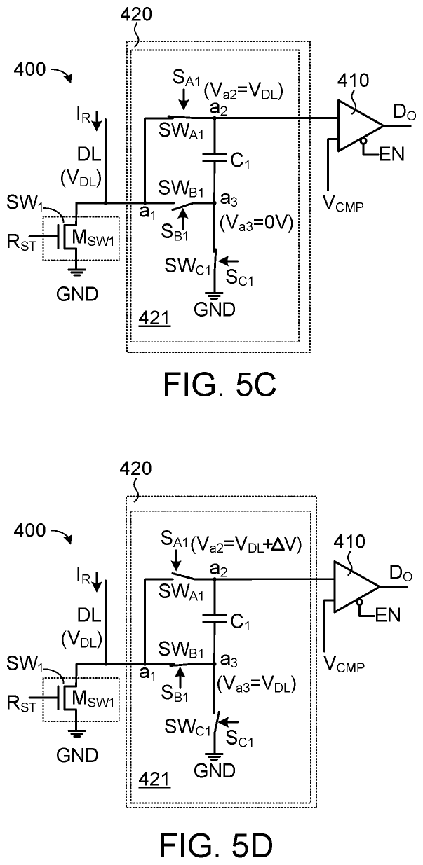

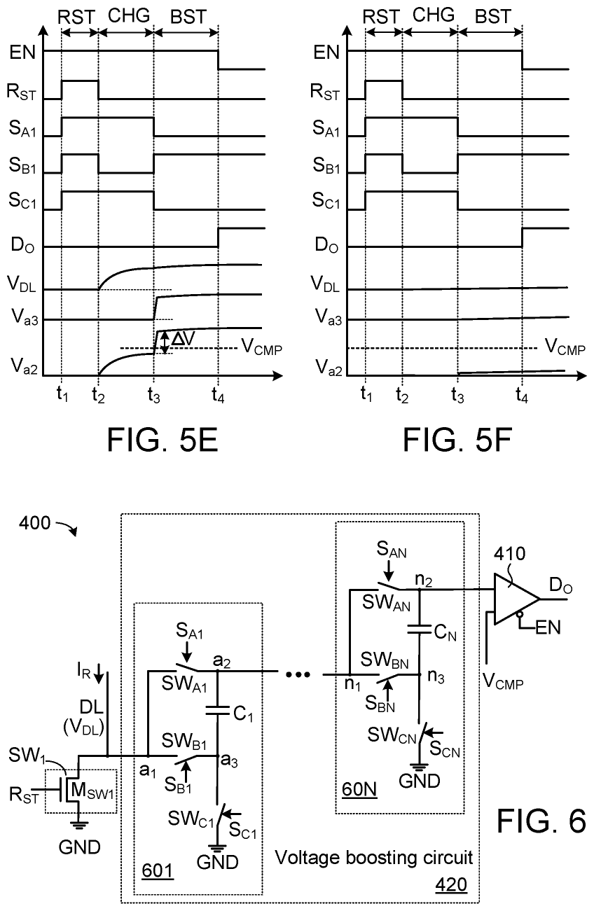

FIG. 5A is a schematic diagram illustrating the detailed circuitry structure of the sense amplifier according to the second embodiment. As shown in FIG. 5A, the voltage boosting circuit 420 comprises a single boosting device 421.

The boosting device 421 comprises three switching devices SW_{A1}, SW_{B1} and SW_{C1} and a capacitor C₁. The node a₁ is an input terminal of the boosting device 421. The node a₂ is an output terminal of the boosting device 421. The input terminal of the boosting device 421 is connected with the data line DL. The output terminal of the boosting device 421 is connected with the comparator 410. In the boosting device 421, the first terminal of the switching device SW_{A1} is connected with the node a₁, the second terminal of the switching device SW_{A1} is connected with the node a₂, and the control terminal of the switching device SW_{A1} receives a control signal S_{A1}. The first terminal of the switching device SW_{B1} is connected with the node a₁. The second terminal of the switching device SW_{B1} is connected with a node a₃. The control terminal of the switching device SW_{B1} receives a control signal S_{B1}. The first terminal of the switching device SW_{C1} is connected with the node a₃. The second terminal of the switching device SW_{C1} is connected with the ground terminal GND. The control terminal of the switching device SW_{C1} receives a control signal S_{C1}. The capacitor C₁ is connected between the node a₂ and the node a₃.

The first input terminal of the comparator 410 receives the comparison voltage V_{CMP}. The second terminal of the comparator 410 is connected with the node a₂. The enable terminal of the comparator 410 receives the enable signal EN. The output terminal of the comparator 410 generates the output data D_{O}. Generally, the node a₂ is the output terminal of the boosting device 421. The node a₂ is served as a sensing node. That is, the second input terminal of the comparator 410 is connected with the sensing node a₂. According to the relationship between a sensing voltage Vₐ₂ at the sensing node and the comparison voltage V_{CMP}, the comparator 410 judges the storage state of the selected memory cell.

FIGS. 5B, 5C and 5D schematically illustrate the operations of the sense amplifier according to the second embodiment of the present invention. FIG. 5E is a schematic timing waveform diagram illustrating associated signals of the sense amplifier when the selected memory cell in the low-resistance state (e.g., the second storage state) is sensed. FIG. 5F is a schematic timing waveform diagram illustrating associated signals of the sense amplifier when the selected memory cell in the high-resistance state (e.g., the first storage state) is sensed.

Please refer to FIGS. 5B and 5E. The time interval between the time point t₁ and t₂ is a reset phase RST of the read action. In the reset phase RST, the reset signal R_{ST} is in the high-level state, the control signals S_{A1}, S_{B1} and S_{C1} are in the high-level state, and the switching devices SW₁, SW_{A1}, SW_{B1} and SW_{C1} are in the close state. Meanwhile, all of the data line voltage V_{DL}, the sensing voltage Vₐ₂ at the sensing node a₂ and the voltage Vₐ₃ at the node as are the ground voltage (0V). That is, the sensing voltage Vₐ₂ at the sensing node a₂ is reset to the ground voltage (0V). Generally, the reset signal R_{ST} is activated in the reset phase RST only, and the reset signal R_{ST} is inactivated in the other phases. In other words, the switching device SW₁ is in the close state in the reset phase RST only, and the switching device SW₁ is in the open state in the other phases.

Please refer to FIGS. 5C and 5E. The time interval between the time point t₂ and t₃ is a charge phase CHG of the read action. In the charge phase CHG, the control signals S_{A1} and S_{C1} are in the high-level state, the control signals S_{B1} is in the low-level state, the switching devices SW_{A1} and SW_{C1} are in the close state, and the switching devices SW_{B1} is in the open state. Meanwhile, the cell current I_{R} charges the data line DL. Consequently, the data line voltage V_{DL} starts to rise. Under control of the voltage boosting circuit 420, the data line voltage V_{DL} is equal to the sensing voltage Vₐ₂ at the sensing node a₂. That is, the sensing voltage Vₐ₂ at the sensing node a₂ is charged to the data line voltage V_{DL}. Moreover, the voltage Vₐ₃ at the node a₃ is the ground voltage (0V).

Please refer to FIGS. 5D and 5E. The time interval between the time point t₅ and t₄ is a boost phase BST of the read action. In the boost phase BST, the control signals S_{A1} and S_{C1} are in the low-level state, the control signal S_{B1} is in the high-level state, the switching devices SW_{A1} and SW_{C1} are in the open state, and the switching devices SW_{B1} is in the close state. Meanwhile, under the control of the voltage boosting circuit 420, the node a₂ is in the floating state. Consequently, the voltage Vₐ₃ at the node a₃ rises from 0V to the data line voltage V_{DL}, and the sensing voltage Vₐ₂ at the sensing node a₂ is boosted to the data line voltage V_{DL} by a voltage increment ΔV through the capacitor C₁. That is, under control of the voltage boosting circuit 420, the sensing voltage Vₐ₂ at the sensing node a₂ is increased by the voltage increment ΔV from the data line voltage V_{DL}. That is, Vₐ₂=V_{DL}+ΔV. Moreover, the voltage increment ΔV is determined according to the coupling ratio of the capacitor C₁.

At the time point t₄, the boost phase BST is ended. Meanwhile, the enable signal EN is activated, and the comparator 410 is enabled. Since the sensing voltage Vₐ₂ at the sensing node a₂ is higher than the comparison voltage V_{CMP}, the comparator 410 generates a high-level state output data D_{O}. The high-level output data D_{O} from the comparator 410 indicates that the selected memory cell is in a low-resistance storage state (e.g., a second storage state).

Similarly, in case that the selected memory cell is in the high-resistance storage state (e.g., the first storage state), the read cycle of the sense amplifier 400 also contains the reset phase RST, the charge phase CHG and the boost phase BST. Please refer to FIG. 5F. In the charge phase CHG, the cell current I_{R} is very low (e.g., nearly zero). Consequently, the data line voltage V_{DL} and the sensing voltage Vₐ₂ at the sensing node a₂ are very low. Then, in the boost phase BST, because the cell current I_{R} is too small to charge the voltage Vₐ₃ at the node a₃, the sensing voltage Vₐ₂ at the sensing node a₂ is barely boosted by the coupled voltage Vₐ₃ at the node a₃ and the sensing voltage Vₐ₂ is maintained at a lower voltage. That is, the sensing voltage Vₐ₂ at the sensing node a₂ is still much lower than the comparison voltage V_{CMP} in the boost phase BST. Consequently, in the end of the boost phase BST (i.e., at the time point t₄), the enable signal EN is activated, and the sensing voltage Vₐ₂ at the sensing node a₂ is lower than the comparison voltage V_{CMP}. Meanwhile, the comparator 410 generates a low-level state output data D_{O}. The low-level output data D_{O} from the comparator 410 indicates that the selected memory cell is in a high-resistance storage state (e.g., a first storage state).

In comparison with the data line voltage V_{DL} in FIG. 3E, the sense amplifier 400 of the present invention charges the data line voltage V_{DL} to a relatively low voltage during the charge phase CHE, so that the drain-source voltage V_{DS} of the selecting transistor M_{SEL} is larger and maintains larger cell current I_{R}. In the boost phase BST, the sensing voltage Vₐ₂ at the sensing node a₂ is boosted from the data line voltage V_{DL} to (V_{DL}+ΔV) by the boosting device 421. Consequently, the sense amplifier 400 can correctly judge the storage state of the selected memory cell.

In this embodiment, before the enable signal EN is activated, the comparator 410 is disabled to reduce the power consumption of the comparator 410. When the enable signal EN is activated, the comparator 410 is enabled to generate output data D_{O}. It is noted that numerous modifications and alterations may be made while retaining the teachings of the invention. For example, in another embodiment, when the read action is performed, the comparator 410 is continuously operated. Consequently, the sense amplifier 400 also can generate the correct output data D_{O}. That is, the comparator 410 of the sense amplifier 400 is not equipped with the enable terminal. When the read action of the comparator 410 is continuously operated, the correct output data D_{O} can be also generated.

FIG. 6 is a schematic circuit diagram illustrating an example of the sense amplifier according to the second embodiment of the present invention, in which the voltage boosting circuit comprises plural boosting devices.

In comparison with the sense amplifier of FIG. 5A, the voltage boosting circuit 420 in the sense amplifier 400 of FIG. 6 comprises N boosting devices 601˜60N, wherein N is a positive integer larger than 1. The N boosting devices 601˜60N are connected between the data line DL and the comparator 410. The circuitry structures of these boosting devices 601˜60N are identical. For succinctness, only the connecting relationships between these boosting devices 601˜60N will be described as follows.

The input terminal a₁ of the first boosting device 601 is connected with the data line DL. The output terminal n₂ of the last (i.e., the N-th) boosting device 60N is connected with the comparator 410. Consequently, the node n₂ is served as a sensing node. The input terminal of each of the other boosting devices is connected with the output terminal of the previous boosting device, and the output terminal of each of the other boosting device is connected with the input terminal of the next boosting device. Moreover, the capacitance values of the capacitors C₁˜C_{N} of the n boosting devices 601˜60N are identical or different. For example, in an implementation example, the capacitor C₁ in the first boosting device 610 has the largest capacitance value. Moreover, the capacitance value of the capacitor in each of the other boosting devices is smaller than the capacitance value of the capacitor in the previous boosting device. The rest may be deduced by analogy. In other words, the capacitor C_{N} of the last boosting device 60N has the smallest capacitance value.

The operations of the plural boosting devices 601˜60N shown in FIG. 6 are similar to the operations of the signal boosting device 421 shown in FIG. 5A. For succinctness, only the operations of the sense amplifier with two boosting devices will be described as follows. The operations of the sense amplifier with other number of boosting devices will not be redundantly described herein.

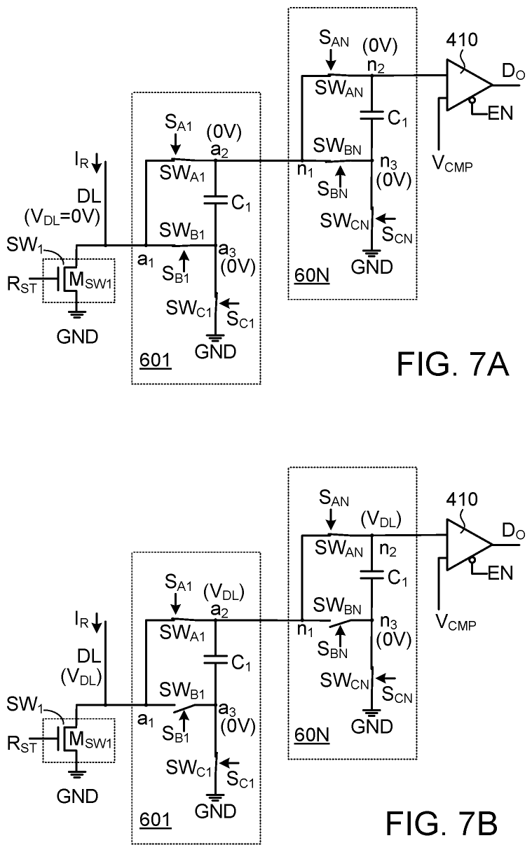

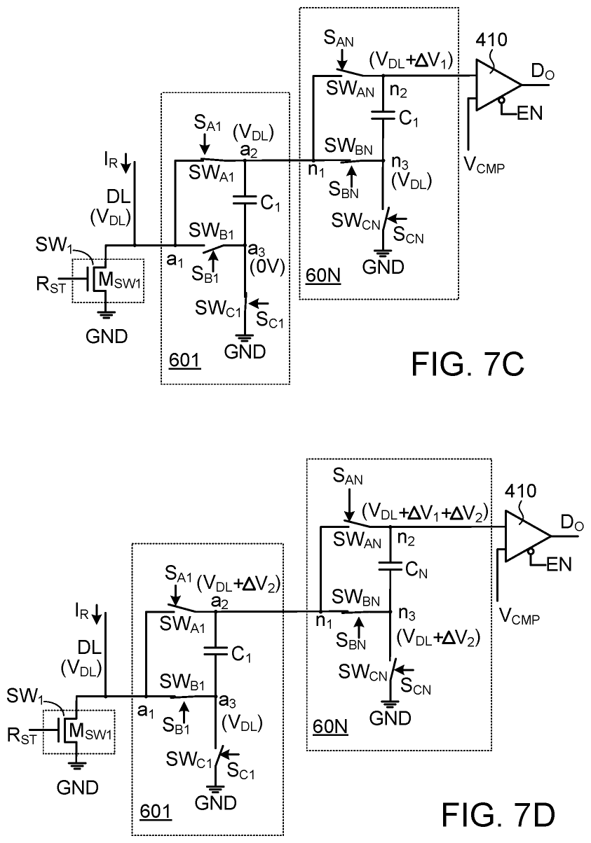

FIGS. 7A, 7B, 7C and 7D schematically illustrate the operations of the sense amplifier according to the second embodiment of the present invention, in which the voltage boosting circuit comprises two boosting devices.

Please refer to FIG. 7A. In the reset phase, all switching devices SW₁, SW_{A1}, SW_{B1}, SW_{C1}, SW_{AN}, SW_{BN} and SW_{CN} are in the close state. Meanwhile, all of the data line voltage V_{DL}, the voltage at the node a₂, the voltage at the node a₃, the voltage at the node n₂ and the voltage at the node n₃ are the ground voltage (0V). That is, in the reset phase, the sensing voltage at the sensing node n₂ is reset to the ground voltage (0V). After the reset phase RST, the switching device SW₁ is in the open state.

Please refer to FIG. 7B. In the charge phase, the switching devices SW_{B1} and SW_{BN} are in the open state, and the switching devices SW_{A1}, SW_{C1}, SW_{AN} and SW_{EN} are in the close state. Meanwhile, the cell current I_{R} charges the data line DL. Consequently, the data line voltage V_{DL} is equal to the voltage at the sensing node a₂ and the voltage at the sensing node n₂. That is, in the charge phase, the sensing voltage at the sensing node n₂ is charged to the data line voltage V_{DL}. Moreover, the voltage at the node as and the voltage at the node n₃ are the ground voltage (0V).

Please refer to FIG. 7C. In the first boost phase, the switching devices SW_{B1}, SW_{AN} and SW_{EN} are in the open state, and the switching devices SW_{A1}, SW_{C1} and SW_{BN} are in the close state. Meanwhile, the data line voltage V_{DL} is equal to the voltage at the sensing node a₂ and the voltage at the sensing node n₃. In addition, the sensing voltage at the sensing node n₂ is boosted to (V_{DL}+ΔV₁). That is, in the first boost phase, the sensing voltage at the sensing node n₂ is boosted to (V_{DL}+ΔV₁). Moreover, the voltage at the node as is the ground voltage (0V).

Please refer to FIG. 7D. In the second boost phase, the switching devices SW_{A1}, SW_{C1}, SW_{AN} and SW_{EN} are in the open state, and the switching devices SW_{B1} and SW_{BN} are in the close state. Meanwhile, the data line voltage V_{DL} is equal to the voltage at the sensing node a₃, and each of the voltage at the node a₂ and the voltage at the node n₃ is boosted to (V_{DL}+ΔV₂). In addition, the sensing voltage at the sensing node n₂ is further boosted to (V_{DL}+ΔV₁+ΔV₂). That is, in the second boost phase, the sensing voltage at the sensing node n₂ is boosted to (V_{DL}+ΔV₁+ΔV₂). Consequently, according to the voltage at the node n₂, the comparator 410 determines the storage state of the selected memory cell.

In the second embodiment, the comparison voltage V_{CMP} is a fixed voltage, and the comparison voltage V_{CMP} is supplied by a power supplier (not shown). In some other embodiments, a voltage generator is provided. The voltage generator comprises a reference memory cell. The reference memory cell generates the cell current. The cell current is generated by the reference memory cell. In addition, the comparison voltage V_{CMP} is generated through the cooperation of the reference memory cell and the voltage boosting circuit.

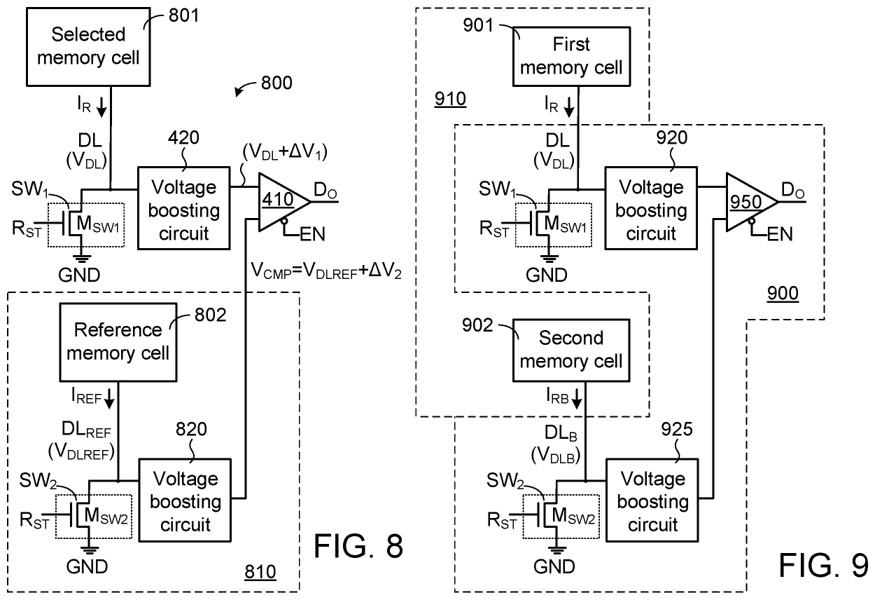

FIG. 8 is a schematic circuit diagram of a sense amplifier according to a third embodiment of the present invention. In comparison with the sense amplifier 400 shown in FIG. 4, the sense amplifier 800 in the third embodiment further comprises a voltage generator 810. For brevity, only the circuitry structure of the voltage generator 810 will be described as follows in more details.

In the memory cell array, the magnitude of the cell current generated by the memory cell in the first storage state (e.g., the high-resistance storage state) and the magnitude of the cell current generated by the memory cell in the second storage state (e.g., the low-resistance storage state) are different. For example, the memory cell in the second storage state generates a cell current of 3 μA, and the memory cell in the first storage state generates a cell current of 0 μA. In the third embodiment, a reference memory cell 802 generates a cell current I_{REF} of 1.5 μA. In other words, in the voltage generator 810, the magnitude of the cell current I_{REF} generated by the reference memory cell 802 is in a range between the magnitude of the cell current generated by the memory cell in the first storage state and the magnitude of the cell current generated by the memory cell in the second storage state. Consequently, when the read action is performed, the selected memory cell 801 is coupled to the data line DL, and the reference memory cell 802 is coupled to a reference data line DL_{REF}. According to the voltages from the two voltage boosting circuits 420 and 820, the comparator 410 determines the storage state of the selected memory cell 801.

The voltage generator 810 comprises the reference memory cell 802, a switching device SW₂ and a voltage boosting circuit 820. The first terminal of the switching device SW₂ is connected with the reference data line DL_{REF}. The second terminal of the switching device SW₂ is connected with the ground terminal GND. The control terminal of the switching device SW₂ receives the reset signal R_{ST}. The input terminal of the voltage boosting circuit 820 is connected with the reference data line DL_{REF}. The output terminal of the voltage boosting circuit 820 generates the comparison voltage V_{CMP} to comparator 410.

In the sense amplifier 800, the two switching devices SW₁ and SW₂ receive the same reset signal R_{ST}. Moreover, the circuitry structures of the two voltage boosting circuits 420 and 820 are identical, and the two voltage boosting circuits 420 and 820 receive the same control signal. For example, in case that the each of two voltage boosting circuits 420 and 820 comprises one boosting device, the three switching devices switching devices SW_{A1}, SW_{B1} and SW_{C1} in the voltage boosting device 420 and the corresponding switching devices switching devices SW_{A1}, SW_{B1} and SW_{C1} in the voltage boosting device 820 are respectively controlled according to the three control signals S_{A1}, S_{B1} and S_{C1} at the same time.

In the reset phase of the read action, the data line DL, the reference data line DL_{REF} and the two input terminals of the comparator 410 are reset to the ground voltage (0V). That is, in the reset phase, the voltage from the output terminal of the voltage boosting circuit 420 is reset to the ground voltage (0V), and the comparison voltage V_{CMP} from the output terminal of the voltage boosting circuit 820 is reset to the ground voltage (0V).

In the charge phase of the read action, the cell current I_{R} generated by the selected memory cell 801 charges the data line DL, and the reference cell current I_{REF} generated by the reference memory cell 802 charges the reference data line DL_{REF}. That is, in the charge phase, the voltage from the output terminal of the voltage boosting circuit 420 is charged to the data line voltage V_{DL}, and the comparison voltage V_{CMP} from the output terminal of the voltage boosting circuit 820 is charged to the reference data line voltage V_{DLREF}.

In the boost phase of the read action, the voltage from the voltage boosting circuit 420 is the data line voltage V_{DL} plus a first voltage increment ΔV₁ (i.e., V_{DL}+ΔV₁), and the voltage from the voltage boosting circuit 820 is the reference data line voltage V_{DLREF} plus a second voltage increment ΔV₂ (i.e., V_{DLREF}+ΔV₂). That is, in the boost phase, the voltage from the output terminal of the voltage boosting circuit 420 is increased to (V_{DL}+ΔV₁), and the comparison voltage V_{CMP} from the output terminal of the voltage boosting voltage 820 is boosted to (V_{DLREF}+ΔV₂). Consequently, according to the voltages from the two voltage boosting circuits 420 and 820, the comparator 410 determines the storage state of the selected memory cell.

According to the similar operating principles, the sense amplifier 800 of the third embodiment can be further applied to a non-volatile memory with differential memory cells. A single differential memory cell comprises two memory cells. After the program action is completed, the two memory cells are respectively in two complementary storage states. For example, in case that the first memory cell is in the high-resistance storage state and the second memory cell is in the low-resistance storage state, the differential memory cell is in the first storage state. Alternatively, in case that the first memory cell is in the low-resistance storage state and the second memory cell is in the high-resistance storage state, the differential memory cell is in the second storage state. In other words, the differential memory cell is a combination of two memory cells to store a 1-bit data.

FIG. 9 is a schematic circuit diagram of a sense amplifier according to a fourth embodiment of the present invention. When the read action is performed, a first memory cell 901 of the selected differential memory cell 910 is coupled to a data line DL, and a second memory cell 902 of the selected differential memory cell 910 is coupled to an inverted data line DL_{B}. In addition, the sense amplifier 900 comprises two switching devices SW₁, SW₂, two voltage boosting circuits 920, 925 and a comparator 950.

The first terminal of the switching device SW₁ is connected with the data line DL. The second terminal of the switching device SW₁ is connected with the ground terminal GND. The control terminal of the switching device SW₁ receives a reset signal R_{ST}. The first terminal of the switching device SW₂ is connected with the inverted data line DL_{B}. The second terminal of the switching device SW₂ is connected with the ground terminal GND. The control terminal of the switching device SW₂ receives the reset signal R_{ST}.

The input terminal of the voltage boosting circuit 920 is connected with the data line DL. The output terminal of the voltage boosting circuit 920 is connected with the first input terminal of the comparator 950. The input terminal of the voltage boosting circuit 925 is connected with the inverted data line DL_{B}. The output terminal of the voltage boosting circuit 925 is connected with the second input terminal of the comparator 950. The enable terminal of the comparator 950 receives the enable signal EN. The output terminal of the comparator 950 generates the output data D_{O}.

Similarly, the two switching devices SW₁ and SW₂ receive the same reset signal R_{ST}. Moreover, the circuitry structures of the two voltage boosting circuits 920 and 925 are identical, and the two voltage boosting circuits 920 and 925 receive the same control signal.

The operations of the sense amplifier 900 are similar to the operations of the sense amplifier 800 in the third embodiment. When the read action is performed by the sense amplifier 900, the read cycle of the sense amplifier 900 also contains the reset phase, the charge phase and the boost phase. Then, according to the voltages from the output terminals of the two voltage boosting circuits 920 and 925, the comparator 950 determines the storage state of the selected differential memory cell.

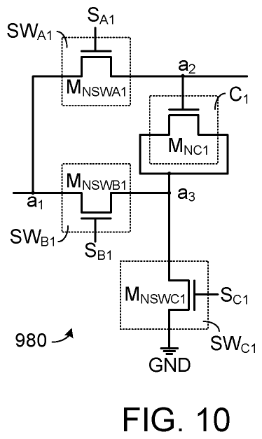

FIG. 10 is a schematic detail circuit diagram illustrating an exemplary boosting device in the sense amplifier of the present invention. Generally, the switching devices SW_{A1}, SW_{B1} and SW_{C1} in the boosting device can be implemented with the n-type transistors.

As shown in FIG. 10, the boosting device 980 comprises switching devices SW_{A1}, SW_{B1} and SW_{C1}, which are respectively implemented with n-type transistors M_{NSWA1}, M_{NSWB1} and M_{NSWC1}. The first source/drain terminal of the transistor M_{NSWA1} is connected with the node a₁. The second source/drain terminal of the transistor M_{NSWA1} is connected with the node a₂. The gate terminal of the transistor M_{NSWA1} receives the control signal S_{A1}. The first source/drain terminal of the transistor M_{NSWB1} is connected with the node a₁. The second source/drain terminal of the transistor M_{NSWB1} is connected with the node a₃. The gate terminal of the transistor M_{NSWB1} receives the control signal S_{B1}. The first source/drain terminal of the transistor M_{NSWC1} is connected with the node a₃. The second source/drain terminal of the transistor M_{NSWC1} is connected with the ground terminal GND. The gate terminal of the transistor M_{NSWC1} receives the control signal S_{C1}. In case that the control signals S_{A1}, S_{B1}, S_{C1} are in the high-level state, the switching devices SW_{A1}, SW_{B1} and SW_{C1} are in the close state. In case that the control signals S_{A1}, S_{B1}, S_{C1} are in the low-level state, the switching devices SW_{A1}, SW_{B1} and SW_{C1} are in the open state. Moreover, the capacitor C₁ is implemented with the n-type transistor M_{NC1}. The gate terminal of the transistor M_{NC1} is connected with the node a₂. The first drain/source terminal and the second drain/source terminal of the transistor M_{NC1} are connected with the node a₃.

Of course, the connecting relationship between the capacitor C₁ and associated components in FIG. 10 may be modified. In a variant example, the first terminal and the second terminal of the transistor M_{NC1} are connected with the node a₂, and the gate terminal of the transistor M_{NC1} is connected with the node a₃. In addition, the transistor M_{NC1} is an n-type depletion transistor.

From the above descriptions, the present invention provides a sense amplifier for a non-volatile memory. The sense amplifier comprises a voltage boosting circuit. The voltage boosting circuit is connected between the data line and the comparator. The sense amplifier of the present invention charges the data line voltage V_{DL} to a relatively low voltage, so that the selected memory cell generates a larger cell current I_{R}. Consequently, the sensing time of the sense amplifier is largely shortened. In addition, the sense amplifier can determine the storage state of the memory cell correctly.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A sense amplifier for a non-volatile memory, a first memory cell of the non-volatile memory being coupled to a data line, the sense amplifier comprising:
a first switching device, wherein a first terminal of the first switching device is connected with the data line, a second terminal of the first switching device is connected with a ground terminal, and a control terminal of the first switching device receives a first control signal, wherein the first control signal is a reset signal;
a first voltage boosting circuit, wherein an input terminal of the first voltage boosting circuit is connected with the data line, and an output terminal of the first voltage boosting circuit is connected with a sensing node; and
a comparator, wherein a first input terminal of the comparator receives a comparison voltage, a second input terminal of the comparator is connected with the sensing node, and an output terminal of the comparator generates an output data,
wherein in a reset phase of a read action, a data line voltage on the data line is reset to a ground voltage, and a sensing voltage at the sensing node is reset to the ground voltage,
wherein in a charge phase of the read action after the reset phase, the first memory cell generates a first cell current to charge the data line, and the sensing voltage is adjusted to the data line voltage under control of the first voltage boosting circuit,
wherein in a boost phase of the read action after the charge phase, the sensing voltage is adjusted to the data line voltage plus a first voltage increment under control of the first voltage boosting circuit,
wherein according to the comparison voltage and the sensing voltage, the comparator generates the output data to determine a storage state of the first memory cell.

2. The sense amplifier as claimed in claim 1, wherein the first switching device is a first transistor, wherein a first drain/source terminal of the first transistor is connected with the data line, a second drain/source terminal of the first transistor is connected with the ground terminal, and a gate terminal of the first transistor receives the first control signal.

3. The sense amplifier as claimed in claim 1, wherein the comparator comprises an enable terminal, and the enable terminal receives an enable signal, wherein when the boost phase of the read action is ended, the enable signal is activated, and the comparator generate the output data according to the comparison voltage and the sensing voltage.

4. The sense amplifier as claimed in claim 1, wherein the first voltage boosting circuit comprises a boosting device, wherein an input terminal of the boosting device is connected with a first node, the first node is connected with the data line, an output terminal of the boosting device is connected with the sensing node, and the boosting device comprises:
a second switching device, wherein a first terminal of the second switching device is connected with the first node, a second terminal of the second switching device is connected with the sensing node, and a control terminal of the second switching device receives a second control signal;
a third switching device, wherein a first terminal of the third switching device is connected with the first node, a second terminal of the third switching devices is connected with a second node, and a control terminal of the third switching device receives a third control signal;
a fourth switching device, wherein a first terminal of the fourth switching device is connected with the second node, a second terminal of the fourth switching device is connected with the ground terminal, and a control terminal of the fourth switching device receives a fourth control signal; and
a first capacitor, wherein a first terminal of the first capacitor is connected with the sensing node, and a second terminal of the first capacitor is connected with the second node.

5. The sense amplifier as claimed in claim 4, wherein in the reset phase of the read action, the first switching device, the second switching device, the third switching device and the fourth switching device are in a close state, and each of the data line voltage and the sensing voltage is reset to the ground voltage, in the charge phase of the read action, the second switching device and the fourth switching device are in the close state, the first switching device and the third switching device are in an open state, and the data line voltage is equal to the sensing voltage, wherein in the boost phase of the read action, the third switching device is in the close state, the first switching device, the second switching device and the fourth switching device are in the open state, and the sensing voltage is equal to the data line voltage plus the first voltage increment.

6. The sense amplifier as claimed in claim 1, wherein the first voltage boosting circuit comprises a boosting device, wherein an input terminal of the boosting device is connected with a first node, the first node is connected with the data line, an output terminal of the boosting device is connected with the sensing node, and the boosting device comprises:
a second transistor, wherein a first drain/source terminal of the second transistor is connected with the first node, a second drain/source terminal of the second transistor is connected with the sensing node, and a gate terminal of the second transistor receives a second control signal;
a third transistor, wherein a first drain/source terminal of the third transistor is connected with the first node, a second drain/source terminal of the third transistors is connected with a second node, and a gate terminal of the third transistor receives a third control signal;
a fourth transistor, wherein a first drain/source terminal of the fourth transistor is connected with the second node, a second drain/source terminal of the fourth transistor is connected with the ground terminal, and a gate terminal of the fourth transistor receives a fourth control signal; and
a first capacitor, wherein a first terminal of the first capacitor is connected with the sensing node, and a second terminal of the first capacitor is connected with the second node.

7. The sense amplifier as claimed in claim 6, wherein the first capacitor comprises a fifth transistor, wherein a first drain/source terminal and a second drain/source terminal of the fifth transistor are connected with the second node, and a gate terminal of the fifth transistor is connected with the sensing node.

8. The sense amplifier as claimed in claim 7, wherein the fifth transistor is a depletion transistor.

9. The sense amplifier as claimed in claim 1, wherein the first voltage boosting circuit comprises N boosting devices, and N is a positive integer larger than 1, wherein in the N boosting devices, an input terminal of a first boosting device is connected with a first node, an output terminal of an N-th is connected with the sensing node, an input terminal of each of the other boosting devices is connected with an output terminal of a previous boosting device, an output terminal of each of the other boosting devices is connected with an input terminal of a next boosting device, and the first node is connected with the data line.

10. The sense amplifier as claimed in claim 9, wherein the first boosting device comprises:
a second switching device, wherein a first terminal of the second switching device is connected with the first node, a second terminal of the second switching device is connected with a second node, the second node is the output terminal of the first boosting device, and a control terminal of the second switching device receives a second control signal;
a third switching device, wherein a first terminal of the third switching device is connected with the first node, a second terminal of the third switching device is connected with a third node, and a control terminal of the third switching device receives a third control signal;
a fourth switching device, wherein a first terminal of the fourth switching device is connected with the third node, a second terminal of the third switching device is connected with the ground terminal, and a control terminal of the fourth switching device receives a fourth control signal; and
a first capacitor, wherein a first terminal of the first capacitor is connected with the second node, and a second terminal of the first capacitor is connected with the third node.

11. The sense amplifier as claimed in claim 9, wherein the first boosting device comprises:
a second transistor, wherein a first drain/source terminal of the second transistor is connected with the first node, a second drain/source terminal of the second transistor is connected with a second node, the second node is the output terminal of the first boosting device, and a gate terminal of the second transistor receives a second control signal;
a third transistor, wherein a first drain/source terminal of the third transistor is connected with the first node, a second drain/source terminal of the third transistor is connected with a third node, and a gate terminal of the third transistor receives a third control signal;
a fourth transistor, wherein a first drain/source terminal of the fourth transistor is connected with the third node, a second drain/source terminal of the third transistor is connected with the ground terminal, and a gate terminal of the fourth transistor receives a fourth control signal; and
a first capacitor, wherein a first terminal of the first capacitor is connected with the second node, and a second terminal of the first capacitor is connected with the third node.

12. The sense amplifier as claimed in claim 11, wherein the first capacitor comprises a fifth transistor, wherein a first drain/source terminal and a second drain/source terminal of the fifth transistor are connected with the third node, and a gate terminal of the fifth transistor is connected with the second node.

13. The sense amplifier as claimed in claim 12, wherein the fifth transistor is a depletion transistor.

14. The sense amplifier as claimed in claim 1, further comprising:
a reference memory cell coupled to a reference data line;
a second switching device, wherein a first terminal of the second switching device is connected with the reference data line, a second terminal of the second switching device is connected with the ground terminal, and a control terminal of the second switching device receives the reset signal; and
a second voltage boosting circuit, wherein an input terminal of the second voltage boosting circuit is connected with the reference data line, and an output terminal of the second voltage boosting circuit is connected with the first input terminal of the comparator, and the output terminal of the second voltage boosting is capable of generating the comparison voltage,
wherein if the first memory cell is in a first storage state, the first memory cell generates a first cell current to the data line when the read action is performed, wherein if the first memory cell is in a second storage state, the first memory cell generates a second cell current to the data line when the read action is performed, wherein a magnitude of a reference cell current generated by the reference memory cell is in a range between the first cell current and the second cell current,
wherein in the reset phase of the read action, a reference data line voltage on the reference data line is reset to the ground voltage, and the comparison voltage is reset to the ground voltage,
wherein in the charge phase of the read action, the reference memory cell generates the reference cell current to charge the reference data line, and the comparison voltage is adjusted to the reference data line voltage under control of the second voltage boosting circuit,
wherein in the boost phase of the read action, the comparison voltage is adjusted to the reference data line voltage plus a second voltage increment under control of the second voltage boosting circuit.

15. The sense amplifier as claimed in claim 1, further comprising:
a second memory cell coupled to an inverted data line, wherein the first memory cell and the second memory cell are collaboratively formed as a differential memory cell;
a second switching device, wherein a first terminal of the second switching device is connected with the inverted data line, a second terminal of the second switching device is connected with the ground terminal, and a control terminal of the second switching device receives the reset signal; and
a second voltage boosting circuit, wherein an input terminal of the second voltage boosting circuit is connected with the inverted data line, and an output terminal of the second voltage boosting circuit is connected with the first input terminal of the comparator, and the output terminal of the second voltage boosting is capable of generating the comparison voltage,
wherein in the reset phase of the read action, an inverted data line voltage on the inverted data line is reset to the ground voltage, and the comparison voltage is reset to the ground voltage,
wherein in the charge phase of the read action, the second memory cell generates a second cell current to charge the inverted data line, and the comparison voltage is adjusted to the inverted data line voltage under control of the second voltage boosting circuit,
wherein in the boost phase of the read action, the comparison voltage is adjusted to the inverted data line voltage plus a second voltage increment under control of the second voltage boosting circuit.
